(19) United States
(12) Patent Application Publication
(10) Pub. No.: US 2016/0372535 A1
(43) Pub. Date: Dec. 22, 2016

(54) DISPLAY DEVICE

(71) Applicant: Samsung Display Co., Ltd., Yongin-si (KR)

(72) Inventors: Wonse Lee, Yongin-si (KR); Donghwi Kim, Yongin-si (KR)

(21) Appl. No.: 14/971,841

(22) Filed: Dec. 16, 2015

(30) Foreign Application Priority Data
Jun. 17, 2015 (KR) 10-2015-0086170

(51) Int. Cl. H01L 27/32; G09G 3/3233; H01L 51/52; G09G 3/20

(52) U.S. Cl. CPC H01L 27/3276; G09G 3/2085; G09G 3/3233; H01L 27/3262; H01L 51/524; G09G 2300/0413

(57) ABSTRACT

A display device is disclosed. In one aspect, the display device includes a substrate comprising an active area and an inactive area adjacent to the active area. Pixels are disposed in the active area at intersections of first signal lines extending in a first direction and second signal lines extending in a second direction crossing the first direction. Each of the pixels comprises a pixel electrode and an opposite electrode facing each other. A plurality of dummy pixels are disposed in the inactive area along the second direction, and a power wire is disposed in the inactive area and connected to at least one of the opposite electrodes. A dummy signal line is electrically connected to the dummy pixels and disposed in the inactive area, and branch lines are configured to electrically connect the dummy signal line to the dummy pixels.

### CROSS-REFERENCE TO RELATED APPLICATION

This application claims the benefit of Korean Patent Application No. 10-2015-0086170, filed on Jun. 17, 2015, in the Korean Intellectual Property Office, the disclosure of which is incorporated herein in its entirety by reference.

### BACKGROUND

Field

The described technology generally relates to a display device.

Description of the Related Technology

Display devices generate images, and recently, organic light-emitting diode (OLED) displays have been highlighted as next generation displays.

OLEDs are self-emissive and do not require a separate light source (unlike a liquid crystal display device), and thus, can be thin and light. Also, OLED technology has favorable characteristics such as low power consumption, high brightness, and quick response rates.

A voltage is supplied from an external source so as to drive the OLED display. The voltage from the external source is provided via voltage wiring formed in the OLED display.

When a defect occurs in a pixel, the pixel may always emit light or may not emit light at all, regardless of the pixel signal transmitted to the defective pixel. The defective pixel is displayed and thus, recognized as a bright spot or a dark spot, and may be additionally repaired.

### SUMMARY OF CERTAIN INVENTIVE ASPECTS

One inventive aspect relates to a display device.

Another aspect is a display device that includes a substrate including an active area and a dead area adjacent to the active area; a plurality of pixels arranged in the active area at intersections of first signal lines extending in a first direction and second signal lines extending in a second direction, wherein each of the pixels includes a pixel electrode and an opposite electrode that face each other; a plurality of dummy pixels arranged in the dead area along the second direction; a power wire disposed in the dead area, and connected to the opposite electrode; a dummy signal line arranged in the dead area; a plurality of branch lines connecting the dummy signal line with the dummy pixels; and a dummy connection line selectively connecting the dummy signal line with one of the second signal lines, wherein the dummy signal line is spaced apart from the dummy pixels with the power wire interposed therebetween.

The dummy signal line may extend in the second direction, and the branch lines may extend in the first direction.

The branch lines may pass through the power wire so as to partially overlap the power wire.

The opposite electrode may cover the active area, and an end portion of the opposite electrode may be spaced apart from the dummy signal line.

The dummy signal line may include a first side adjacent to the power wire, and a second side opposite to the first side, and the end portion of the opposite electrode may be spaced apart from the first side.

The pixels may include a defective pixel, and a second signal line that is among the second signal lines and corresponds to the defective pixel may be disconnected from the dummy signal line.

The display device may further include a first driving unit that applies a first signal to each of the first signal lines; and a second driving unit that applies a second signal to each of the second signal lines.

The first driving unit may be disposed between the power wire and the dummy pixels.

The branch lines may pass through the power wire and the first driving unit so as to partially overlap the power wire and the first driving unit.

Each of the pixels may include a pixel circuit connected to the pixel electrode, and each of the dummy pixels may include a dummy pixel circuit.

The display device may further include repair lines that selectively connect the dummy pixels with the pixels.

The display device may further include an encapsulation substrate that faces the substrate; and a sealing member that is interposed between the encapsulation substrate and the dead area of the substrate and surrounds the active area.

The dummy signal line may be disposed between the sealing member and the power wire.

The display device may further include a thin encapsulation film that is disposed on the substrate and includes an organic layer and an inorganic layer.

The first signal lines may include a scan line, and the second signal lines may include a data line.

Another aspect is a display device, comprising: a substrate comprising an active area and an inactive area adjacent to the active area; a plurality of pixels disposed in the active area at intersections of a plurality of first signal lines extending in a first direction and a plurality of second signal lines extending in a second direction crossing the first direction, wherein each of the pixels comprises a pixel electrode and an opposite electrode facing each other; a plurality of dummy pixels disposed in the inactive area along the second direction; a power wire disposed in the inactive area and connected to at least one of the opposite electrodes; a dummy signal line electrically connected to the dummy pixels and disposed in the inactive area; a plurality of branch lines configured to electrically connect the dummy signal line to the dummy pixels; and a dummy connection line configured to selectively connect the dummy signal line to one of the second signal lines, wherein the dummy signal line is spaced apart from the dummy pixels with the power wire interposed therebetween.

In the above display device, the dummy signal line extends in the second direction, wherein the branch lines extend in the first direction.

In the above display device, the branch lines pass through the power wire so as to partially overlap the power wire.

In the above display device, the opposite electrode of each of the pixels covers the active area, wherein an end portion of each of the opposite electrodes is spaced apart from the dummy signal line.

In the above display device, the dummy signal line comprises a first side adjacent to the power wire and a second side opposite to the first side, wherein the end portion of the opposite electrode is spaced apart from the first side.

In the above display device, the pixels comprise a defective pixel, wherein a selected second signal line among the second signal lines corresponds to the defective pixel, wherein the selected second signal is disconnected from the dummy signal line.

The above display device further comprises: a first driving circuit configured to apply a first signal to each of the first signal lines; and a second driving circuit configured to apply a second signal to each of the second signal lines.

In the above display device, the first driving circuit is disposed between the power wire and the dummy pixels.

In the above display device, the branch lines pass through the power wire and the first driving circuit so as to partially overlap the power wire and the first driving circuit.

In the above display device, each of the pixels comprises a pixel circuit connected to the pixel electrode, wherein each of the dummy pixels comprises a dummy pixel circuit.

The above display device further comprises a plurality of repair lines configured to selectively connect the dummy pixels to the pixels.

The above display device further comprises: an encapsulation substrate facing the substrate; and a sealing member interposed between the encapsulation substrate and the inactive area of the substrate, wherein the sealing member surrounds the active area.

In the above display device, the dummy signal line is disposed between the sealing member and the power wire.

The above display device further comprises a thin encapsulation film disposed on the substrate and including an organic layer and an inorganic layer.

In the above display device, the first signal lines comprise a scan line, and wherein the second signal lines comprise a data line.

Another aspect is a display device, comprising: a plurality of pixels each comprising a pixel electrode and an opposite electrode facing each other; a plurality of dummy pixels located adjacent to the pixels; a power wire connected to at least one of the opposite electrodes; and a dummy signal line electrically connected to the dummy pixels and located adjacent to the power wire; wherein the dummy signal line does not overlap the power wire in the depth dimension of the display device.

The above display device further comprises a first driving circuit configured to electrically connect the dummy signal line to the dummy pixels via a branch line.

The above display device further comprises a dummy connection line configured to selectively connect the dummy signal line to a second signal line.

In the above display device, the pixels are disposed in a plurality of rows, wherein the display device further comprises a repair line connected to a selected one of the dummy pixels and the pixels in the same row as the selected dummy pixel.

In the above display device, the dummy signal line is spaced apart from the power wire in the row direction of the rows of the pixels.

### BRIEF DESCRIPTION OF THE DRAWINGS

FIG. 1 is a block diagram of a display device, according to an exemplary embodiment.

FIG. 2 illustrates the display unit, the dummy pixel unit, and the signal lines of FIG. 1.

FIG. 3 illustrates transmission of a signal due to a repair process performed when the display unit of FIG. 2 includes a defective pixel.

FIG. 4 is a circuit diagram illustrating a dummy pixel, a pixel, and a defective pixel that is repaired according to an exemplary embodiment.

FIG. 5 is a plan view illustrating a portion of the display device, according to an exemplary embodiment.

FIG. 6 is a plan view illustrating a portion VI of FIG. 5.

FIG. 7 is a cross-sectional view, taken along a line VII-VII of FIG. 6.

FIG. 8 is a cross-sectional view of a display device, according to another exemplary embodiment.

### DETAILED DESCRIPTION OF CERTAIN INVENTIVE EMBODIMENTS

As the described technology allows for various changes and numerous embodiments, particular embodiments will be illustrated in the drawings and described in detail in the written description. The effects and features of the described technology will now be described more fully with reference to the accompanying drawings, in which exemplary embodiments are shown. The described technology may, however, be embodied in many different forms and should not be construed as being limited to the embodiments set forth herein.

Those components that are the same or are in correspondence are rendered the same reference numeral regardless of the figure number, and redundant explanations are omitted.

Throughout the specification, while such terms as “first,” “second,” etc., may be used to describe various components, such components must not be limited to the above terms. The above terms are used only to distinguish one component from another.

Throughout the specification, a singular form may include plural forms, unless there is a particular description contrary thereto.

Throughout the specification, terms such as “comprise” or “comprising” are used to specify existence of features and/or components described in the specification, not excluding the existence of one or more other features and/or one or more other components.

It will be understood that when a layer, an area, a component, or the like is referred to as being “on” another layer, area, or component can be directly on another layer, area, or component or intervening layer, area, or component may also be present.

In the drawings, the thicknesses of layers and regions are exaggerated for clarity. For example, the thicknesses and sizes of elements in the drawings are arbitrarily shown for convenience of description, thus, the spirit and scope of the described technology are not necessarily defined by the drawings.

Also, it should also be noted that in some alternative implementations, the steps of all methods described herein may occur out of the order. For example, two steps illustrated in succession may in fact be executed substantially concurrently or the two steps may sometimes be executed in the reverse order.

Throughout the specification, it will also be understood that when an element such as layer, region, or component is referred to as being “connected to” or “coupled with” another element, it can be directly connected to or coupled with the other element, or intervening elements may also be present. For example, throughout the specification, when an element such as layer, region, or component is referred to as being “electrically connected to” or “electrically coupled with” another element, it can be directly and electrically connected to or coupled with the other element, or intervening elements may also be present.

As used herein, the term “and/or” includes any and all combinations of one or more of the associated listed items. Expressions such as “at least one of,” when preceding a list of elements, modify the entire list of elements and do not modify the individual elements of the list. In this disclosure, the term “substantially” includes the meanings of completely, almost completely or to any significant degree under some applications and in accordance with those skilled in the art.

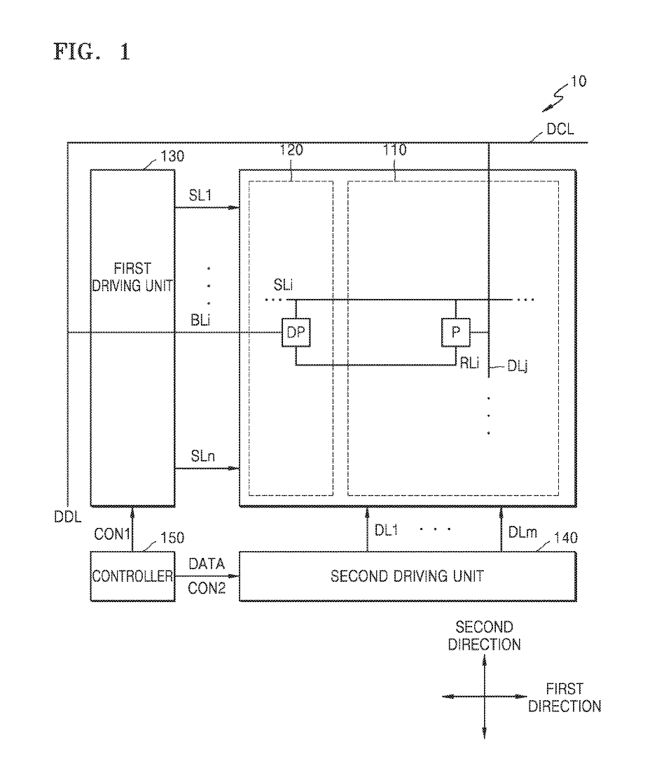

FIG. 1 is a block diagram of a display device 10 according to an exemplary embodiment.

The display device 10 may include a display unit 110 including a plurality of pixels P, a dummy pixel unit 120 including a plurality of dummy pixels DP, a first driving unit (or first driving circuit) 130, a second driving unit (or second driving circuit) 140, and a controller 150. At least one of the first driving unit 130 and the second driving unit 140 may be formed on the same substrate as the plurality of pixels P and the dummy pixels DP.

The first driving unit 130 may sequentially drive first signal lines SL1 through SLn of the first driving unit 130, in response to a first control signal CON1 of the controller 150 to be described later. The first driving unit 130 may generate a first signal, e.g., a scan signal, and may provide the first signal to each of the pixels P and each of the dummy pixels DP via the first signal lines SL1 through SLn.

The second driving unit 140 may sequentially drive second signal lines DL1 through DLm of the second driving unit 140, in response to a second control signal CON2 of the controller 150. The second driving unit 140 may generate a second signal, e.g., a data signal, and may provide the second signal to each of the pixels P via the second signal lines DL1 through DLm.

In response to a vertical synchronization signal and a horizontal synchronization signal, the controller 150 generates the first control signal CON1 for controlling the first driving unit 130 and the second control signal CON2 for controlling the second driving unit 140, and transmits the first control signal CON1 and the second control signal CON2 to the first driving unit 130 and the second driving unit 140, respectively. The controller 150 converts image signals received from an external source to image data signals DATA, and then, transfers the image data signals DATA to the second driving unit 140.

The display unit 110 may include the pixels P that are disposed at intersections of the first signal lines SL1 through SLn and the second signal lines DL1 through DLm in a matrix form. The first signal lines SL1 through SLn extend in a first direction that is a row direction, and the second signal lines DL1 through DLm extend in a second direction that is a column direction.

The dummy pixel unit 120 includes the dummy pixels DP that are arrayed adjacent to the pixels P. For example, the dummy pixels DP are arrayed adjacent to the pixels P in the second direction. The dummy pixels DP may be connected to a corresponding first signal line (e.g., a first signal line SLi) among the first signal lines SL1 through SLn, and each of the dummy pixels DP may be selectively connected to a pixel P disposed on the same row, via a repair line (e.g., a repair line RLi). In some exemplary embodiments, the repair line RLi overlaps a wire (not shown) of the pixel P while an insulating layer (not shown) is interposed therebetween. Afterward, in a repair process, the insulating layer is removed by a laser, etc., so that the wire of the pixel P and the repair line RLi may be connected.

In some exemplary embodiments, the dummy pixel unit 120 is disposed on a left side and/or a right side of the display unit 110. In other embodiments, the dummy pixel unit 120 may be disposed on an upper side and/or a lower side of the display unit 110.

A dummy signal line DDL may be formed in parallel with the second signal lines DL1 through DLm. When the display unit 110 includes a defective pixel, the dummy signal line DDL functions as a repair-use second signal line that is connected, via the repair process, to a second signal line (e.g., a second signal line DLj) corresponding to the defective pixel and transmits a data signal. The dummy signal line DDL is connected to a dummy pixel DP via a branch line (e.g., a branch line BLi) that extends in the first direction.

The dummy signal line DDL may be selectively connected to the second signal lines DL1 through DLm via a dummy connection line DCL. The dummy connection line DCL may be connected to the dummy signal line DDL and may be selectively connected to the second signal lines DL1 through DLm. In some exemplary embodiments, the dummy connection line DCL overlaps the second signal lines DL1 through DLm by having an insulating layer interposed therebetween. Afterward, in the repair process, the insulating layer is removed by a laser, etc., so that the dummy connection line DCL and a second signal line (e.g., the second signal line DLj) among the second signal lines DL1 through DLm may be connected to each other. Since the dummy connection line DCL is connected to the dummy signal line DDL, the second signal line DLj that was connected to the dummy connection line DCL in the repair process is connected to the dummy signal line DDL.

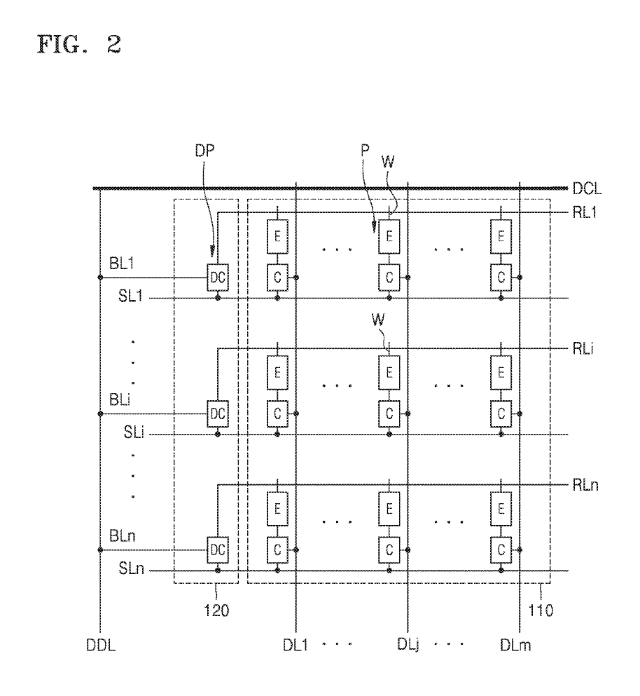

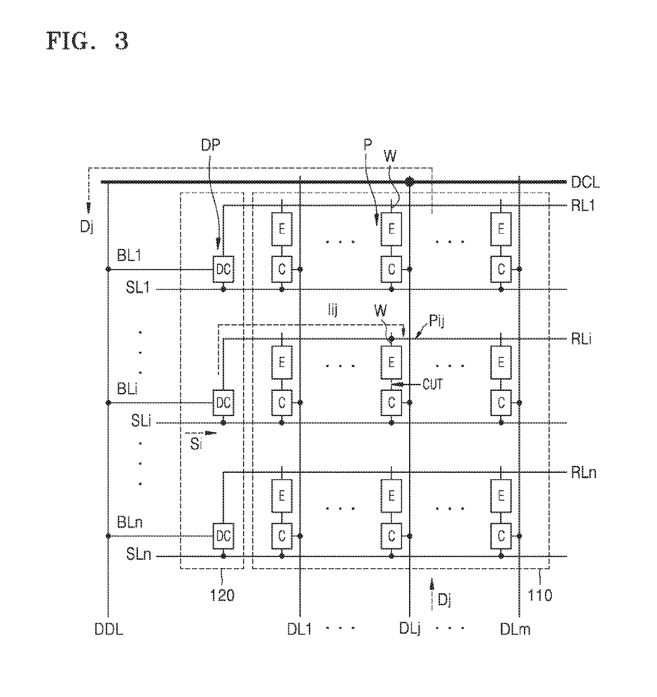

FIG. 2 illustrates the display unit 110, the dummy pixel unit 120, and signal lines of FIG. 1, and FIG. 3 illustrates transmission of a signal due to a repair process performed when the display unit 110 of FIG. 2 includes a defective pixel.

Referring to FIG. 2, each of the pixels P of the display unit 110 may include a pixel circuit C and a light-emitting device E that emits light by receiving a driving current from the pixel circuit C. In some exemplary embodiments, the pixel P emits light having one of red, green, blue, and white colors. The pixel circuits C are respectively connected to the first signal lines SL1 through SLn that extend in the first direction and the second signal lines DL1 through DLm that extend in the second direction.

Each of the dummy pixels DP of the dummy pixel unit 120 may include a dummy pixel circuit DC. Unlike the pixel P of the display unit 110, the dummy pixel DP does not include a light-emitting device and thus does not emit light.

The dummy pixel circuits DC are connected to the first signal lines SL1 through SLn that extend in the first direction and are connected to the dummy signal line DDL that extends in the second direction. A first signal line (e.g., the first signal line SLi) among the first signal lines SL1 through SLn is connected to pixel circuits C and a dummy pixel circuit DC that are arrayed on the same row. The dummy pixel circuits DC are connected to the dummy signal line DDL via branch lines BL1 through BLn extending from the dummy signal line DDL in the first direction.

Each of the dummy pixel circuits DC may be selectively connected to the light-emitting devices E of the pixels P on the same row via repair lines RL1 through RLn. In some exemplary embodiments, the repair lines RL1 through RLn are connected to the dummy pixel circuits DC and overlap wires W, which extend from the light-emitting devices E of the pixels P, by having an insulating layer interposed therebetween. Afterward, in a repair process, when a laser is irradiated onto an overlapping region of a repair line (e.g., a repair line RLi) and the wire W, the insulating layer between the repair line RLi and the wire W is destroyed. Then, the repair line RLi and the wire W are connected to each other.

The dummy connection line DCL is connected to the dummy signal line DDL and is selectively connected to the second signal lines DL1 through DLm. In some exemplary embodiments, the dummy connection line DCL extending in the first direction and the second signal lines DL1 through DLm extending in the second direction overlap each other with an insulating layer interposed therebetween. Afterward, in the repair process, when a laser is irradiated onto an overlapping region of a second signal line (e.g., a second signal line DLj) and the dummy connection line DCL, the insulating layer between the second signal line DLj and the dummy connection line DCL is destroyed. Then, the second signal line DLj and the dummy connection line DCL are connected to each other.

Throughout the specification, each of the pixels P of the display unit 110 may include a plurality of sub-pixels that display a plurality of colors. Throughout the specification, one pixel P may indicate one sub-pixel. However, the described technology is not limited thereto, and the pixel P may indicate one unit pixel including a plurality of sub-pixels. That is, in the specification, if there is one pixel P, it may mean that there is one sub-pixel or it may mean that there are a plurality of sub-pixels. This may also be applied to a dummy pixel DP. For example, throughout the specification, one dummy pixel DP includes one dummy pixel circuit. Alternatively, if one pixel P includes a plurality of sub-pixels, one dummy pixel DP may include dummy pixel circuits that correspond to the number of sub-pixels.

Hereinafter, with reference to FIG. 3, repairing process will be described, and it is assumed that a pixel Pij that is among the pixels P of the display unit 110 and is connected to an i^{th} first signal line SLi and a j^{th} second signal line DLj is defective. For convenience of description, the pixel Pij is referred to as a defective pixel Pij.

Referring to FIG. 3, a light-emitting device E of the defective pixel Pij is disconnected from a pixel circuit C. In some exemplary embodiments, the connection between the light-emitting device E and the pixel circuit C of the defective pixel Pij is cut by using a laser, so that the light-emitting device E of the defective pixel Pij may be electrically disconnected from the pixel circuit C of the defective pixel Pij.

Next, the second signal line DLj that is among the second signal lines DL1 through DLm and corresponds to the defective pixel Pij is connected onto a dummy signal line DDL. In some exemplary embodiments, a laser is irradiated onto an overlapping region of the second signal line DLj and a dummy connection line DCL, so that the second signal line DLj of the defective pixel Pij and the dummy connection line DCL are connected to each other. Since the dummy connection line DCL is already connected to the dummy signal line DDL, the second signal line DLj of the defective pixel Pij and the dummy signal line DDL are connected to each other via the irradiation of the laser.

Next, the light-emitting device E of the defective pixel Pij is connected to a dummy pixel circuit DC of a dummy pixel DP disposed on the same row as the defective pixel Pij. In some exemplary embodiments, a repair line RLi that corresponds to the defective pixel Pij overlaps a wire W of the defective pixel Pij by having an insulating layer interposed therebetween. Afterward, a laser is irradiated onto an overlapping region of the repair line RLi and the wire W of the defective pixel Pij, so that the repair line RLi and the wire W of the defective pixel Pij are connected to each other. Since the repair line RLi is already connected to the dummy pixel circuit DC, the light-emitting device E of the defective pixel Pij and the dummy pixel circuit DC are connected to each other.

The dummy pixel circuit DC of the defective pixel Pij and the pixel circuit C of the defective pixel Pij are connected to the same first signal line SLi, and thus substantially simultaneously respond to a scan signal Si applied thereto via the first signal line SLi.

Since the second signal line DLj that is connected to the pixel circuit C of the defective pixel Pij is connected to the dummy signal line DDL via the dummy connection line DCL, a data signal Dj that is applied via the second signal line DLj is applied to the dummy pixel circuit DC via the dummy signal line DDL and a branch line BLi that is connected to the dummy signal line DDL. The dummy pixel circuit DC generates a driving current Iij corresponding to the data signal Dj, and the driving current Iij is provided to the light-emitting device E of the defective pixel Pij via the repair line RLi. Therefore, the light-emitting device E of the defective pixel Pij may emit light as a normal pixel P.

With reference to FIG. 3, in a repair process, the light-emitting device E of the defective pixel Pij is disconnected from the pixel circuit C, the second signal line DLj of the defective pixel Pij is connected to the dummy signal line DDL, and then the light-emitting device E of the defective pixel Pij is connected to the dummy pixel circuit DC, but a repair order may be changed.

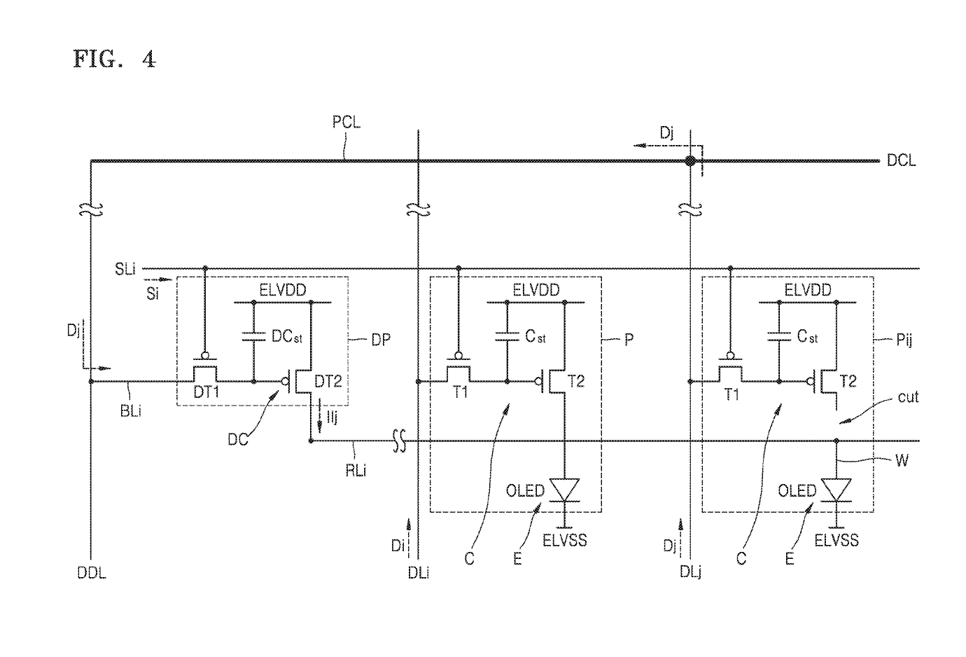

FIG. 4 is a circuit diagram illustrating the dummy pixel DP, a pixel P, and the defective pixel Pij of FIG. 3.

Referring to FIG. 4, the pixel P includes a light-emitting device E and a pixel circuit C. The light-emitting device E may be an organic light-emitting diode (OLED) that includes a pixel electrode and an opposite electrode facing each other, and an emission layer interposed between the pixel electrode and the opposite electrode. The pixel circuit C may include first and second thin-film transistors T1 and T2, and a capacitor Cst.

The first thin-film transistor T1 includes a gate electrode connected to a first signal line SLi, a first electrode connected to a second signal line DLj, and a second electrode connected to a gate electrode of the second thin-film transistor T2 and the capacitor Cst. One of the first electrode and the second electrode is a source electrode and the other one is a drain electrode.

The second thin-film transistor T2 includes the gate electrode connected to the second electrode of the first thin-film transistor T1, a first electrode to which a first power voltage ELVDD is applied, and a second electrode connected to the OLED. One of the first electrode and the second electrode of the second thin-film transistor T2 is a source electrode and the other one is a drain electrode. The capacitor Cst includes a first electrode connected to the second electrode of the first thin-film transistor T1, and a second electrode to which the first power voltage ELVDD is applied.

The first thin-film transistor T1 transmits a data signal Dj to the first electrode of the capacitor Cst, wherein the data signal Dj is supplied from the second signal line DLj when a scan signal Si is supplied from the first signal line SLi. The capacitor Cst is charged by a voltage corresponding to the data signal Dj, a driving current corresponding to the voltage that was charged in the capacitor Cst is delivered to the OLED via the second thin-film transistor T2, and thus the light-emitting device E emits light. The opposite electrode of the OLED receives a second power voltage ELVSS from an external source. The second power voltage ELVSS may be a ground voltage.

In the present exemplary embodiment, the pixel circuit C includes the first and second thin-film transistors T1 and T2, and the capacitor Cst, but the described technology is not limited thereto. In another exemplary embodiment, the pixel circuit C includes at least two thin-film transistors and one or more capacitors.

The dummy pixel DP is disposed on the same row as the pixel P, does not include a light-emitting device, and only includes a dummy pixel circuit DC. The dummy pixel circuit DC may include first and second dummy thin-film transistors DT1 and DT2, and a dummy capacitor DCst.

The first dummy thin-film transistor DT1 may be connected to the first signal line SLi and may be connected to a dummy signal line DDL via a branch line BLi, and the second dummy thin-film transistor DT2 and the dummy capacitor DCst may be connected between a first power voltage ELVDD and the first dummy thin-film transistor DT1.

In the present exemplary embodiment, the dummy pixel circuit DC includes the first and second dummy thin-film transistors DT1 and DT2, and the dummy capacitor DCst, but the described technology is not limited thereto. In another exemplary embodiment, the dummy pixel circuit DC includes at least two dummy thin-film transistors and one or more dummy capacitors.

When the defective pixel Pij is generated, a light-emitting device E of the defective pixel Pij may not be connected to a pixel circuit C of the defective pixel Pij but may be electrically connected to the dummy pixel circuit DC disposed on the same row. As described above with reference to FIG. 3, the pixel circuit C and the light-emitting device E of the defective pixel Pij are electrically disconnected by using a laser, etc., a second signal line DLj of the defective pixel Pij is connected to a dummy connection line DCL by using a laser, etc., and a repair line RLi is connected to the light-emitting device E of the defective pixel Pij by using a laser, etc.

The dummy pixel circuit DC responses to the scan signal Si applied via the first signal line SLi, receives the data signal Dj applied to the defective pixel Pij, and generates a driving current Iij. Since the driving current Iij is provided to the light-emitting device E of the defective pixel Pij via the repair line RLi, an OLED that is the light-emitting device E of the defective pixel Pij may normally operate.

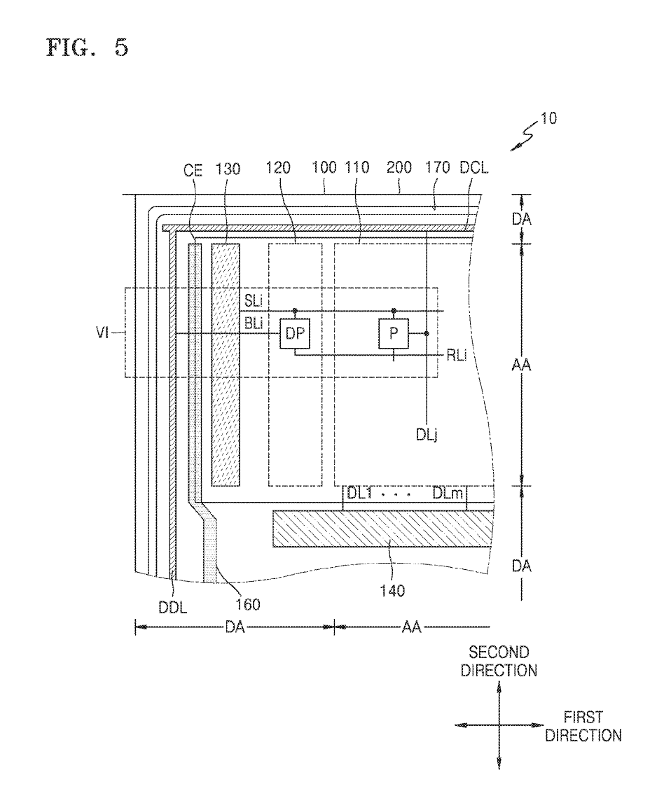

FIG. 5 is a plan view illustrating a portion of the display device 10, according to an exemplary embodiment. The display device 10 of FIG. 5 may correspond to exemplary embodiments of the display device 10 described above with reference to FIGS. 1 through 4.

Referring to FIG. 5, the display device 10 includes a substrate 100 including an active area AA and a dead area (or inactive area) DA, the display unit 110 formed in the active area AA, the dummy pixel unit 120 formed in the dead area DA, the first and second driving units 130 and 140, a controller (not shown) that controls the first and second driving units 130 and 140, and a power wire 160. The display unit 110 may be protected from an outside air, due to the substrate 100, an encapsulation substrate 200 facing the substrate 100, and a sealing member 170 interposed between the substrate 100 and the encapsulation substrate 200.

The display unit 110 includes a plurality of pixels P each disposed at an intersection of first signal lines SL1 through SLn extending in a first direction and second signal lines DL1 through DLm extending in a second direction. The pixels P may be arrayed in the first direction and the second direction so as to form a matrix. As described above with reference to FIGS. 1 through 4, each of the pixels P may include an OLED and a pixel circuit C. The pixel circuit C may include at least two thin-film transistors and at least one capacitor.

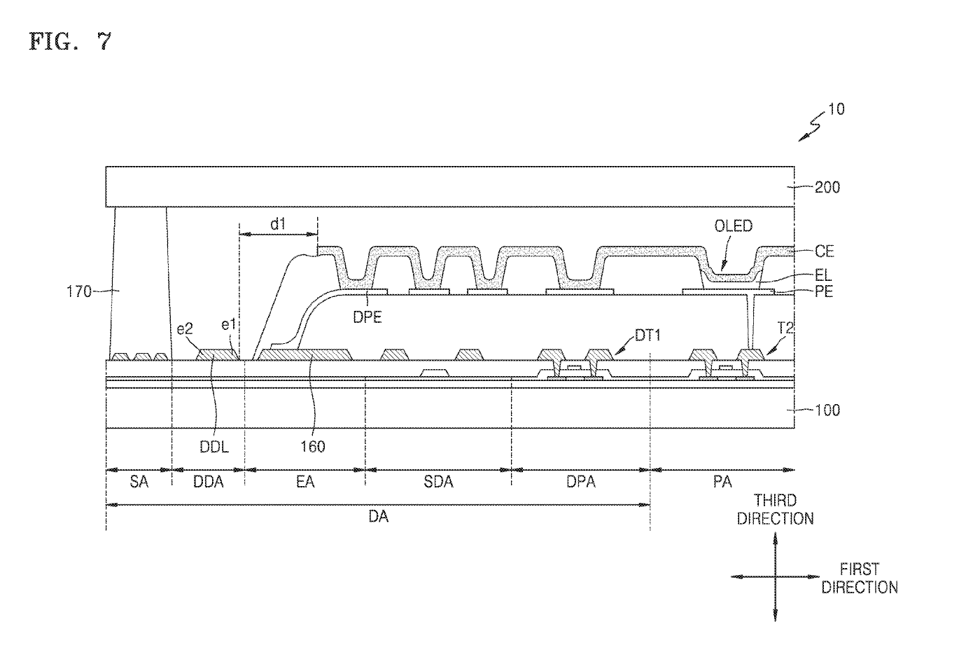

The OLED may include a pixel electrode PE (refer to FIG. 7) and an opposite electrode CE that face each other, and an emission layer EL (refer to FIG. 7) interposed between the pixel electrode PE and the opposite electrode CE. The pixel electrode PE may have an island form that is patterned in each pixel P. The opposite electrode CE may have one body so as to cover all of the pixels P. The opposite electrode CE is connected to the power wire 160 formed in the dead area DA and thus receives a second power voltage ELVSS.

The dummy pixel unit 120 may be disposed at a periphery of the display unit 110 so as to be adjacent to the display unit 110. Referring to FIG. 5, the dummy pixel unit 120 is disposed on a left side of the display unit 110 but the described technology is not limited thereto. In another exemplary embodiment, the dummy pixel unit 120 is disposed on a right side, an upper side and/or a lower side of the display unit 110. The dummy pixel unit 120 includes a plurality of dummy pixels DP that are arrayed in the second direction.

The first driving unit 130 may be disposed in the dead area DA, and may be a scan driving unit that provides a scan signal Si to a dummy pixel DP and a pixel P via first signal lines SL1 through SLn that extend in the first direction. In some exemplary embodiments, the first driving unit 130 is disposed between the dummy pixel unit 120 and the power wire 160. The first driving unit 130 may be simultaneously formed when the pixel circuit C and a dummy pixel circuit DC are formed on the substrate 100.

The second driving unit 140 may be disposed in the dead area DA, and may be a data driving unit that provides a data signal Dj to the pixel P via second signal lines DL1 through DLm that extend in a second direction. In some exemplary embodiments, the second driving unit 140 is substantially simultaneously (concurrently) formed when the pixel circuit C and the dummy pixel circuit DC are formed on the substrate 100.

A dummy signal line DDL may extend in the dead area DA along the second direction, and may be selectively connected to the second signal lines DL1 through DLm via a dummy connection line DCL that extends in the dead area DA along the first direction. In some exemplary embodiments, the dummy connection line DCL overlaps the second signal lines DL1 through DLm, and an insulating layer (not shown) is interposed between the dummy connection line DCL and the second signal lines DL1 through DLm. Afterward, as described above, in a repair process, the insulating layer is removed due to laser irradiation, so that the dummy signal line DDL is selectively connected to the second signal lines DL1 through DLm.

The dummy signal line DDL may be disposed in an outer side of the power wire 160 without overlapping the opposite electrode CE. In a comparative example, if the dummy signal line DDL and the opposite electrode CE are formed to overlap each other, parasitic capacitance may be generated between the opposite electrode CE and the dummy signal line DDL. The parasitic capacitance may affect the data signal Dj that is transmitted via the dummy signal line DDL, such that an OLED of a defective pixel P does not normally emit light.

However, according to one or more exemplary embodiments, the dummy signal line DDL is disposed in the outer side of the power wire 160 so as not to overlap the opposite electrode CE, so that generation of the parasitic capacitance between the dummy signal line DDL and the opposite electrode CE may be significantly reduced or may be prevented.

In some exemplary embodiments, in order to prevent generation of parasitic capacitance between the opposite electrode CE and the dummy connection line DCL, the dummy connection line DCL is disposed outwardly spaced apart from an end of the opposite electrode CE, so as not to overlap the dummy connection line DCL.

The dummy signal line DDL is connected to each of the dummy pixels DP via branch lines BLi that extend in the first direction. Since the dummy signal line DDL is disposed in the outer side of the power wire 160, the branch lines BLi may extend to the dummy pixels DP via the power wire 160.

A repair line RLi extends in the first direction so as to selectively connect a dummy pixel DP and an OLED of a pixel P that are disposed on the same row. In some exemplary embodiments, the repair line RLi is formed to overlap a wire W connected to the OLED of the pixel P, and an insulating layer (not shown) is interposed between the repair line RLi and the wire W. Afterward, as described above, in the repair process, the insulating layer is destroyed due to laser irradiation, so that the repair line RLi and the OLED of the pixel P are selectively connected.

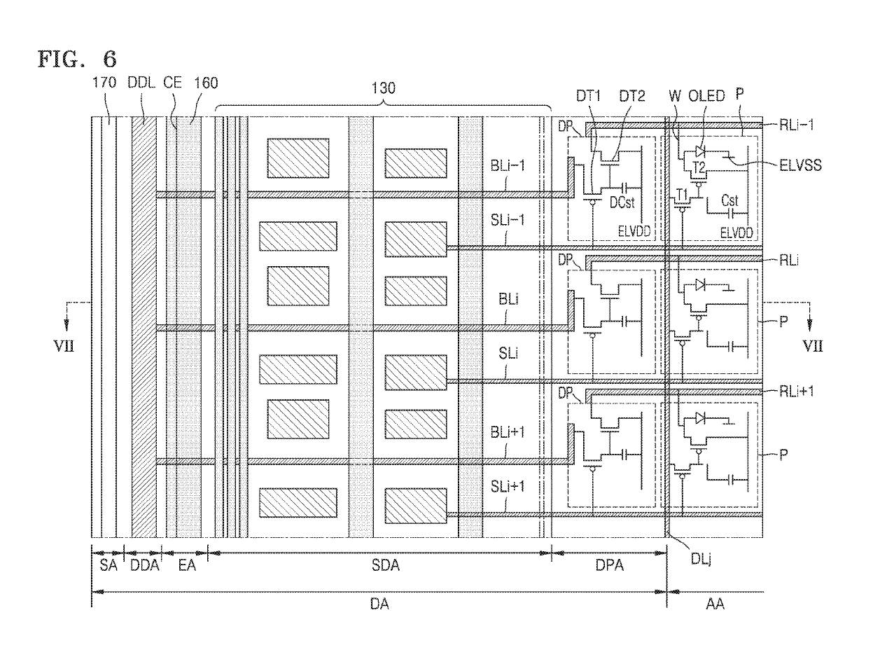

FIG. 6 is a plan view illustrating a portion VI of FIG. 5. FIG. 7 is a cross-sectional view, taken along a line VII-VII of FIG. 6.

Referring to FIGS. 6 and 7, in an active area AA, the display unit 110 including a plurality of pixels P is arranged, and in a dead area DA, the dummy pixel unit 120, the first driving unit 130, the power wire 160, a dummy signal line DDL, and the sealing member 170 are sequentially disposed in this order in a direction away from the display unit 110. For example, the dead area DA includes a dummy pixel area DPA where the dummy pixel unit 120 is arranged, a first driving area SDA where the first driving unit 130 is arranged, a power area EA where the power wire 160 is arranged, a dummy signal area DDA where the dummy signal line DDL is arranged, and a sealing area SA where the sealing member 170 is arranged.

Each pixel P may include first and second thin-film transistors T1 and T2, a capacitor Cst, and an OLED that is electrically connected to the first and second thin-film transistors T1 and T2 and the capacitor Cst, and each dummy pixel DP may include first and second dummy thin-film transistors DT1 and DT2, and a dummy capacitor DCst. First signal lines SLi−1, SLi, and SLi+1 are connected to gate electrodes of the first thin-film transistors T1 of the pixels P and gate electrodes of the first dummy thin-film transistors DT1 of the dummy pixels DP, respectively, so that a scan signal is applied to each of the pixels P and each of the dummy pixels DP. The first thin-film transistor T1 of each pixel P is connected to a second signal line DLj, so that a data signal Dj is applied to each pixel P. A first power voltage ELVDD is applied to the second thin-film transistor T2 of each pixel P and the second dummy thin-film transistor DT2 of each dummy pixel P, an opposite electrode CE of the OLED has one body so as to cover the active area AA and a portion of the dead area DA, and receives a second power voltage ELVSS from the power wire 160. As illustrated in FIG. 7, one or more connection units DPE are interposed between the opposite electrode CE and the power wire 160 and thus electrically connect the opposite electrode CE to the power wire 160.

The dummy signal line DDL is disposed to be spaced apart from the opposite electrode CE in the first direction. For example, the dummy signal line DDL includes a first side e1 adjacent to the power wire 160, and a second side e2 distant from the power wire 160. In this regard, the first side e1 is spaced apart from an end of the opposite electrode CE by a distance dl.

In some exemplary embodiments, the dummy signal line DDL is disposed between the sealing member 170 and the opposite electrode CE. Since the dummy signal line DDL and the opposite electrode CE do not overlap each other, the generation of parasitic capacitance between the dummy signal line DDL and the opposite electrode CE may be prevented or may be significantly reduced, therefore, when a defective pixel is repaired, an organic light-emitting device of the defective pixel may normally operate.

Branch lines BLi−1, BLi, and BLi+1 that extend from the dummy signal line DDL in the first direction are connected to the dummy pixels DP disposed on same rows. The branch lines BLi−1, BLi, and BLi+1 may pass through the power wire 160 and the first driving unit 130 that are disposed between the dummy signal line DDL and the dummy pixel unit 120. Here, in order to prevent the branch lines BLi−1, BLi, and BLi+1 from being electrically connected to the power wire 160 and wires and devices such as thin-film transistors, etc. that are included in the first driving unit 130, the branch lines BLi−1, BLi, and BLi+1 may be formed on a layer different from a layer of the power wire 160 and the wires and the devices of the first driving unit 130, by having an insulating layer interposed therebetween. The second dummy thin-film transistors DT2 of dummy pixel circuits DC that are connected to the branch lines BLi−1, BLi, and BLi+1 are connected to repair lines RLi−1, RLi, and RLi+1 that extend toward the pixels P arranged on same rows. The repair lines RLi−1, RLi, and RLi+1 extend along the first direction so as to respectively overlap the wires W by having an insulating layer interposed therebetween, wherein the wires W extend from the OLED of the pixels P. In this regard, as described above with reference to FIGS. 1 through 4, the repair lines RLi−1, RLi, and RLi+1 are connected to the wires W in the repair process.

Referring to FIG. 6, it is assumed that each of the dummy pixels DP and the pixels P includes two thin-film transistors and one capacitor, but according to the circuit, the number of thin-film transistors and capacitor may be increased.

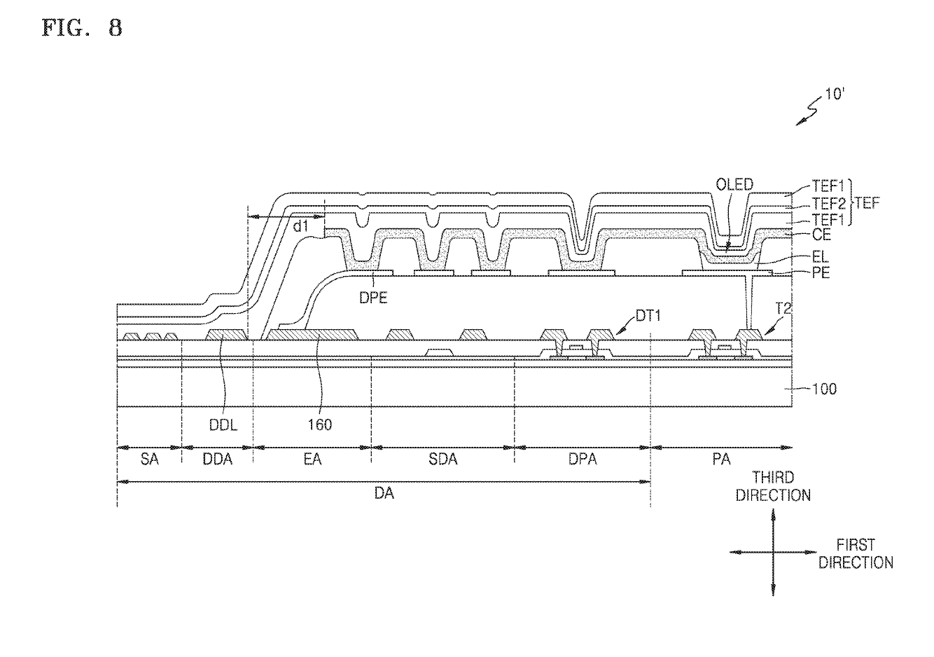

FIG. 8 is a cross-sectional view of a display device 10′, according to another exemplary embodiment.

Referring to FIG. 8, the display device 10′ according to the present exemplary embodiment is different from the display device 10 described with reference to FIGS. 5 through 7 in that a display unit 110 of the display device 10′ is not encapsulated by a sealing member 170 and an encapsulation substrate 200, and the display device 10′ includes a thin encapsulation film TEF. Same configurations correspond to what are described above, and hereinafter, only differences therebetween will now be described.

The thin encapsulation film TEF may include an organic layer TEF1 and an inorganic layer TEF2, and may protect the display unit 110 from an outside air or moisture. In some exemplary embodiments, the organic layer TEF1 has a structure where the organic layer TEF1 and the inorganic layer TEF2 are alternately stacked. An order of stacking and the number of the organic layer TEF1 and the inorganic layer TEF2 may be changed if required.

The thin encapsulation film TEF may cover all of an active area AA and a dead area DA. As described above with reference to FIGS. 1 through 7, a dummy signal line DDL is disposed in an outer side of a power wire 160 in a first direction away from the display unit 110, so that the dummy signal line DDL may not overlap an opposite electrode CE and may be spaced apart from the opposite electrode CE. The dummy signal line DDL that does not overlap the opposite electrode CE and is exposed may be covered by the thin encapsulation film TEF.

According to at least one of the disclosed embodiments, in a display device, a dummy signal line that is used in repairing a defective pixel is formed in an outer side of a power line connected to an opposite electrode, therefore, an overlapping of the dummy signal line and the opposite electrode may be prevented, and generation of parasitic capacitance between the dummy signal line and the opposite electrode may be prevented or may be significantly reduced.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While the inventive technology has been described with reference to the figures, it will be understood by those of ordinary skill in the art that various changes in form and details may be made therein without departing from the spirit and scope as defined by the following claims.

What is claimed is:

1. A display device, comprising:
a substrate comprising an active area and an inactive area adjacent to the active area;
a plurality of pixels disposed in the active area at intersections of a plurality of first signal lines extending in a first direction and a plurality of second signal lines extending in a second direction crossing the first direction, wherein each of the pixels comprises a pixel electrode and an opposite electrode facing each other;
a plurality of dummy pixels disposed in the inactive area along the second direction;
a power wire disposed in the inactive area and connected to at least one of the opposite electrodes;
a dummy signal line electrically connected to the dummy pixels and disposed in the inactive area;
a plurality of branch lines configured to electrically connect the dummy signal line to the dummy pixels; and
a dummy connection line configured to selectively connect the dummy signal line to one of the second signal lines,
wherein the dummy signal line is spaced apart from the dummy pixels with the power wire interposed therebetween.

2. The display device of claim 1, wherein the dummy signal line extends in the second direction, and wherein the branch lines extend in the first direction.

3. The display device of claim 1, wherein the branch lines pass through the power wire so as to partially overlap the power wire.

4. The display device of claim 1, wherein the opposite electrode of each of the pixels covers the active area, and wherein an end portion of each of the opposite electrodes is spaced apart from the dummy signal line.

5. The display device of claim 4, wherein the dummy signal line comprises a first side adjacent to the power wire and a second side opposite to the first side, and
wherein the end portion of the opposite electrode is spaced apart from the first side.

6. The display device of claim 1, wherein the pixels comprise a defective pixel, wherein a selected second signal line among the second signal lines corresponds to the defective pixel, and wherein the selected second signal is disconnected from the dummy signal line.

7. The display device of claim 1, further comprising:
a first driving circuit configured to apply a first signal to each of the first signal lines; and
a second driving circuit configured to apply a second signal to each of the second signal lines.

8. The display device of claim 7, wherein the first driving circuit is disposed between the power wire and the dummy pixels.

9. The display device of claim 8, wherein the branch lines pass through the power wire and the first driving circuit so as to partially overlap the power wire and the first driving circuit.

10. The display device of claim 1, wherein each of the pixels comprises a pixel circuit connected to the pixel electrode, and wherein each of the dummy pixels comprises a dummy pixel circuit.

11. The display device of claim 10, further comprising a plurality of repair lines configured to selectively connect the dummy pixels to the pixels.

12. The display device of claim 1, further comprising:
an encapsulation substrate facing the substrate; and
a sealing member interposed between the encapsulation substrate and the inactive area of the substrate, wherein the sealing member surrounds the active area.

13. The display device of claim 12, wherein the dummy signal line is disposed between the sealing member and the power wire.

14. The display device of claim 1, further comprising a thin encapsulation film disposed on the substrate and including an organic layer and an inorganic layer.

15. The display device of claim 1, wherein the first signal lines comprise a scan line, and wherein the second signal lines comprise a data line.

16. A display device, comprising:
a plurality of pixels each comprising a pixel electrode and an opposite electrode facing each other;
a plurality of dummy pixels located adjacent to the pixels;
a power wire connected to at least one of the opposite electrodes; and
a dummy signal line electrically connected to the dummy pixels and located adjacent to the power wire;
wherein the dummy signal line does not overlap the power wire in the depth dimension of the display device.

17. The display device of claim 16, further comprising a first driving circuit configured to electrically connect the dummy signal line to the dummy pixels via a branch line.

18. The display device of claim 17, further comprising a dummy connection line configured to selectively connect the dummy signal line to a second signal line.

19. The display device of claim 18, wherein the pixels are disposed in a plurality of rows, and wherein the display device further comprises a repair line connected to a selected one of the dummy pixels and the pixels in the same row as the selected dummy pixel.

20. The display device of claim 19, wherein the dummy signal line is spaced apart from the power wire in the row direction of the rows of the pixels.
